(19) United States
(12) Patent Application Publication
(10) Pub. No.: US 2015/0318506 A1
(43) Pub. Date: Nov. 5, 2015

(54) ORGANIC LIGHT EMITTING DIODE DISPLAY APPARATUS

(71) Applicant: BOE TECHNOLOGY GROUP CO., LTD., Beijing (CN)

(72) Inventors: Li ZHOU, Beijing (CN); Yue LI, Beijing (CN)

(21) Appl. No.: 14/345,721

(22) PCT Filed: May 28, 2013
(86) PCT No.: PCT/CN2013/076305

§ 371 Date: Mar. 19, 2014

(30) Foreign Application Priority Data
Apr. 23, 2013 (CN) 201310142081.4

(51) Int. Cl. H01L 51/50; H01L 27/32

(52) U.S. Cl. CPC H01L 51/502; H01L 27/322; H01L 27/3211; H01L 2251/301; H01L 2251/303

(57) ABSTRACT

An organic light emitting diode display apparatus includes a light-emitting module and a color filter layer that includes a plurality of sub-pixels, wherein at least one of the sub-pixels contains a quantum dot material; the light-emitting module includes a plurality of light-emitting units corresponding to the plurality of sub-pixels on the color filter layer.

### TECHNICAL FIELD

Embodiments of the present invention relate to an organic light emitting diode (OLED) display apparatus.

### BACKGROUND

Recently, due to the rapid development of information technology, display devices for various electronic equipments become very important. An existing OLED display apparatus may include a transparent substrate and a plurality of light-emitting units provided on the transparent substrate, and the light-emitting unit may include an anode, a hole transportation layer, a luminescent module, an electron transportation layer and a cathode. Each of the light-emitting units is driven by one TFT (thin film transistor) in correspondence with it to emit light, and corresponds to one sub-pixel. An OLED display apparatus can be made to be lighter and thinner because it has less layer structures, and its luminescent module is capable of emitting light by itself to save electrical energy remarkably, it has developed and matured gradually, and has began to occupy the display market gradually.

Among various types of existing OLEDs, a RGB trichrome OLED has a relatively complex production process, and is not easy to achieve high resolution; while a white OLED adopts a structure of a light-emitting module plus RGB color filters above the module and is easier to achieve high resolution, despite the fact that RGB color filters have lower transmittance and may affect brightness of the display apparatus. As for an OLED with RGBW color filters, the brightness of the display apparatus is increased by addition of one pixel W, but this may affect gamut of the display apparatus.

### SUMMARY

According to embodiments of the present invention, there is provided an organic light emitting diode (OLED) display apparatus, so that high resolution can be realized and the display quality of the display apparatus is enhanced.

In one aspect of the invention, there is provided an organic light emitting diode display apparatus, comprising a light-emitting module and a color filter layer that includes a plurality of sub-pixels, wherein at least one of the sub-pixels contains a quantum dot material; and the light-emitting module includes a plurality of light-emitting units corresponding to the plurality of sub-pixels on the color filter layer.

For example, the sub-pixels correspond to three colors of red, green and blue.

For example, a sub-pixel corresponding to red on the color filter layer contains a red-emitting quantum dot, a sub-pixel corresponding to green on the color filter layer contains a green-emitting quantum dot, and a sub-pixel corresponding to blue on the color filter layer contains a blue-emitting quantum dot; light-emitting units in the light-emitting module emit lights that can excite the red-emitting quantum dot, the green-emitting quantum dot and the blue-emitting quantum dot.

For example, the sub-pixels have three colors of red, green and blue correspondingly; the light-emitting units on the light-emitting module are light-emitting units for emitting blue light; a sub-pixel corresponding to red on the color filter layer contains a red-emitting quantum dot, a sub-pixel corresponding to green on the color filter layer contains a green-emitting quantum dot, and a sub-pixel corresponding to blue on the color filter layer contains a transparent material.

For example, the blue-emitting light-emitting units on the light-emitting module are organic light emitting diodes capable of emitting blue light.

For example, the quantum dot includes: a nucleus; a shell formed outside the nucleus, and organic ligands formed on the outside of the shell.

For example, the nucleus of the quantum dot is formed by mixing one or more materials selected from the group consisting of ZnS, ZnO, GaN, ZnSe, CdS, ZnTe, GaSe, CdSe, CdTe, GaAs, InP, GaSb, InAs, Te, PbS, InSb, PbTe and PbSe.

For example, the shell of the quantum dot is formed from any one of SiO, TiO, ZnO, SiO2 and MgO.

For example, the organic ligands include S, P, COOH and NH4 groups.

### BRIEF DESCRIPTION OF THE DRAWINGS

In order to illustrate the technical solution of the embodiments of the invention more clearly, the drawings of the embodiments will be briefly described below; it is obvious that the drawings as described below are only related to some embodiments of the invention, but not limitative of the invention.

FIG. 1 is a structurally schematic view illustrating an OLED display apparatus provided by an embodiment of the invention;

FIG. 2 is a schematically top view illustrating the structure of a substrate with color filters formed thereon provided by an embodiment of the invention; and

FIG. 3 is a structurally schematic view illustrating a quantum dot provided by an embodiment of the invention.

### DESCRIPTION OF THE REFERENCE NUMERALS

11—transparent substrate; 12—color filter layer, 121—pixel region, 1211—sub-pixel; 13—light-emitting module, 131—light-emitting unit.

### DETAILED DESCRIPTION

In order to make objects, technical details and advantages of the embodiments of the invention apparent, hereinafter, the technical solutions of the embodiments of the invention will be described in a clearly and fully understandable way in connection with the drawings related to the embodiments of the invention. It is obvious that the described embodiments are just a part but not all of the embodiments of the invention. Based on the described embodiments of the invention, those ordinarily skilled in the art can obtain other embodiment(s), without any inventive work, which come(s) within the scope sought for protection by the invention.

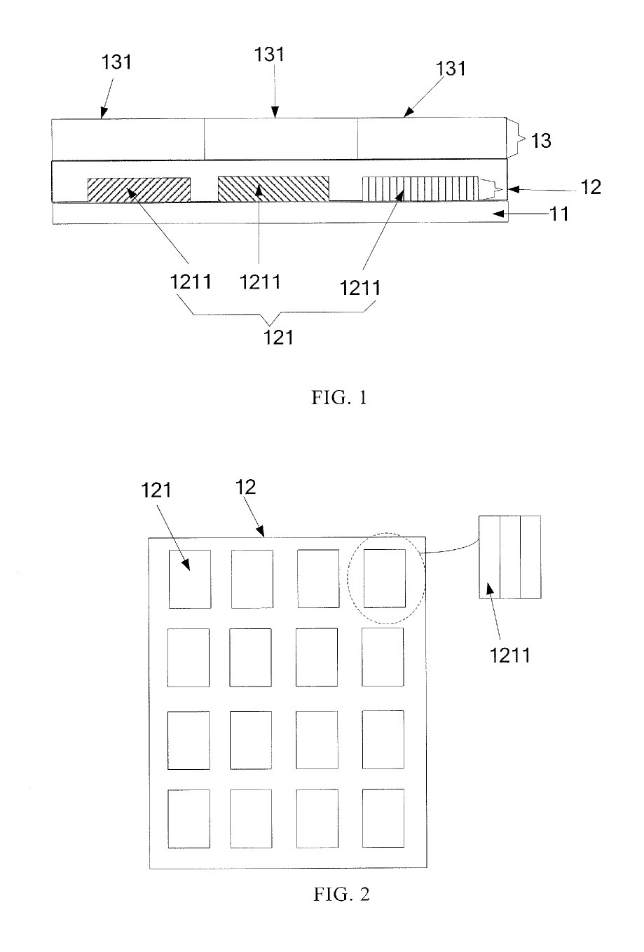

According to an embodiment of the invention, there is provided an organic light emitting diode display apparatus. As shown in FIG. 1, it includes a transparent substrate 11, and a color filter layer 12, and a light-emitting module 13 provided on the transparent substrate 11.

As shown in FIG. 1, the color filter layer 12 includes a plurality of sub-pixels 1211, and at least one of the sub-pixels is formed of a quantum dot material.

For example, as shown in FIG. 2 which is a schematically top view illustrating the structure of a substrate with color filters produced thereon, the color filter layer 12 includes a plurality of pixel regions 121, and each of the pixel regions 121 includes three sub-pixels 1211. Each of the sub-pixel regions 1211 of the three sub-pixels corresponds to a respective color, and for example these colors are red, green and blue, respectively; at least one of the sub-pixels is formed of a quantum dot material; the color of the light that is generated due to the excitation of the quantum dot material is the same as the corresponding color of the sub-pixel region; the other sub-pixel regions may be formed of filter films of the corresponding color; and the filter films here refer to color filter film applied to a liquid crystal display panel.

The light-emitting module 13 is disposed over the color filter layer 12, and includes a plurality of light-emitting units 131 corresponding to sub-pixel regions 1211 on the color filter layer 12 in a one-to-one correspondence relationship. That is, for the sub-pixel regions 1211 on the color filter layer 12, the same number of light-emitting units 131 corresponding to them are provided in the light-emitting module 13. For example, each of the light-emitting units 131 includes an anode, a hole transportation layer, a light emitting layer, an electron transportation layer, and a cathode. Each light-emitting unit is controlled by a respective TFT, and capable of emitting light separately. The invention is not limited to the concrete construction of the light-emitting units.

Although in FIG. 1, the color filter layer 12 is disposed over the substrate 11 and the light-emitting module 13 is disposed over the color filter layer 12, locations of the color filter layer 12 and the light-emitting module 13 can be interchanged with each other. Namely, in another embodiment, a light-emitting module 13 is disposed over a substrate 11 and a color filter layer 12 is disposed over the light-emitting module 13. The OLED display apparatuses according to the embodiments of the invention differ in the light-emitting direction in these two manners.

There is no liquid crystal layer in an OLED display apparatus, and brightness of each sub-pixel region is controlled by a light-emitting unit corresponding to the sub-pixel region. Each light-emitting unit is provided above one sub-pixel region in correspondence, and driven by a TFT corresponding to it independently to emit light, and the luminous intensity may be different from each other. That is, the OLED can adopt an active driving mode, but also can adopt a passive driving mode. Lights emitted from it can have different colors after they pass through pixel regions in the color filter layer, so that images can be displayed by the OLED display apparatus.

In the embodiment of the invention, at least one of the sub-pixel regions in the color filter layer 12 is formed of a quantum dot material; and the other sub-pixel region(s) is/are formed of filter film(s) with corresponding color(s). The color rendered by the light that is generated from the quantum dot material due to its excitation is the same as the corresponding color of the sub-pixel region. For example, there may be two kinds of method for producing quantum dots into color filer films as follows. One kind is that, quantum dots are dissolved in an organic solvent, and are sprayed on a substrate by way of a spray-coating (similar to ink-jet printing) method so as to form a color filter film; and the other kind is that, by way of imprint that is similar to anastatic printing, quantum dots are printed on a silicon wafer with a pattern without solvent, and then the quantum dots are transferred to a substrate so as to form a color filter film.

The OLED display apparatus provided by an embodiment of the invention includes a light-emitting module and a color filter layer, at least one sub-pixel in the color filter contains a quantum dot material, and light in various colors can be generated by the light emitted from light-emitting units in the light-emitting module after the light pass through the color filter layer, so as to achieve high resolution. Moreover, a color filter formed of the quantum dot material will emit light as well after it is excited by a light-emitting unit, and thereby the brightness of the display apparatus can be increased, so that images displayed by the display apparatus have a better color representation and are more lively, and the display quality of the display apparatus is enhanced.

In another embodiment of the invention, each pixel region includes three sub-pixel regions, which correspond to three colors of red, green and blue, respectively. Luminescent spectrum of the quantum dot material is relatively sharp, and the chromaticity is pure, and therefore, for the sake of endowing the OLED display apparatus with a high resolution and making the displayed image better, all the sub-pixels in the color filter layer can be made to contain a quantum dot material. Namely, a sub-pixel corresponding to red on the color filter layer contains a red-emitting quantum dot, a sub-pixel corresponding to green on the color filter layer contains a green-emitting quantum dot, and a sub-pixel corresponding to blue on the color filter layer contains a blue-emitting quantum dot. Light-emitting units in the light-emitting module may emit light that excites the red-emitting quantum dot, the green-emitting quantum dot and the blue-emitting quantum dot.

Preferably, the light-emitting units in the light-emitting module may be light-emitting units for emitting blue light; a sub-pixel corresponding to red on the color filter layer contains a red-emitting quantum dot, a sub-pixel corresponding to green on the color filter layer contains a green-emitting quantum dot, a sub-pixel corresponding to blue on the color filter layer contains a transparent material. Because light-emitting units in the light-emitting module are made of a same material that emits blue light, a display device of high resolution is produced conveniently.

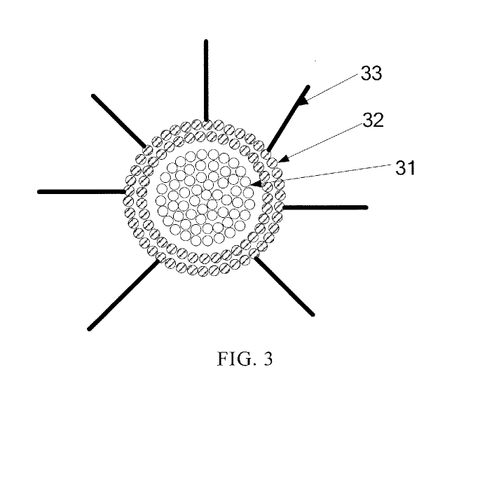

As shown in FIG. 3, the quantum dot may include: a nucleus 31; a shell 32 formed outside the nucleus 31 and organic ligands 33 formed on the outside of the shell 32. The nucleus 31 of the quantum dot may be formed by mixing one or at least two of materials selected from the group consisting of ZnS, ZnO, GaN, ZnSe, CdS, ZnTe, GaSe, CdSe, CdTe, GaAs, InP, GaSb, InAs, Te, PbS, InSb, PbTe and PbSe. The shell 32 of the quantum dot may be formed from any one of SiO, TiO, ZnO, SiO2 and MgO. The organic ligands 33 of the quantum dot include S, P, COOH and NH4 groups. The core-shell structure of the quantum dot shown in FIG. 3 is helpful for the quantum dot to emit light, the organic ligands located on the outside of the shell facilitates dissolution of quantum dots in an organic solvent, in favor of production of the quantum-dot color filter.

Descriptions made above are merely exemplary embodiments of the invention, but are not used to limit the protection scope of the invention. The protection scope of the invention is determined by attached claims.

1. An Organic Light Emitting Diode display apparatus, comprising a light-emitting module and a color filter layer, wherein
the color filter layer includes a plurality of sub-pixels, at least one of the sub-pixels contains a quantum dot material;
the light-emitting module includes a plurality of light-emitting units corresponding to the plurality of sub-pixels on the color filter layer.

2. The display apparatus claimed as claim 1, wherein the sub-pixels have three colors of red, green and blue correspondingly;
a sub-pixel corresponding to red on the color filter layer contains a red-emitting quantum dot, a sub-pixel corresponding to green on the color filter layer contains a green-emitting quantum dot, and a sub-pixel corresponding to blue on the color filter layer contains a blue-emitting quantum dot;
light-emitting units in the light-emitting module emit light that excites the red-emitting quantum dot, the green-emitting quantum dot and the blue-emitting quantum dot.

3. The display apparatus claimed as claim 1, wherein the sub-pixels have three colors of red, green and blue correspondingly;
the light-emitting units in the light-emitting module are light-emitting units for emitting blue light;
a sub-pixel corresponding to red on the color filter layer contains a red-emitting quantum dot, a sub-pixel corresponding to green on the color filter layer contains a green-emitting quantum dot, and a sub-pixel corresponding to blue on the color filter layer contains a transparent material.

4. The display apparatus claimed as claim 3, wherein the light-emitting units for emitting blue light on the light-emitting module are organic light emitting diodes for emitting blue light.

5. The display apparatus claimed as claim 1, wherein the quantum dot includes: a nucleus; a shell formed outside the nucleus, and organic ligands formed on the outside of the shell.

6. The display apparatus claimed as claim 5, wherein the nucleus of the quantum dot is formed by mixing one or more of materials selected from the group consisting of ZnS, ZnO, GaN, ZnSe, CdS, ZnTe, GaSe, CdSe, CdTe, GaAs, InP, GaSb, InAs, Te, PbS, InSb, PbTe and PbSe;
the shell of the quantum dot is formed from any one of SiO, TiO, ZnO, SiO2 and MgO;
the organic ligands include S, P, COOH and NH4 groups.

7. The display apparatus claimed as claim 2, wherein the quantum dot includes: a nucleus; a shell formed outside the nucleus, and organic ligands formed on the outside of the shell.

8. The display apparatus claimed as claim 7, wherein the nucleus of the quantum dot is formed by mixing one or more of materials selected from the group consisting of ZnS, ZnO, GaN, ZnSe, CdS, ZnTe, GaSe, CdSe, CdTe, GaAs, InP, GaSb, InAs, Te, PbS, InSb, PbTe and PbSe;
the shell of the quantum dot is formed from any one of SiO, TiO, ZnO, SiO2 and MgO;
the organic ligands include S, P, COOH and NH4 groups.

9. The display apparatus claimed as claim 3, wherein the quantum dot includes: a nucleus; a shell formed outside the nucleus, and organic ligands formed on the outside of the shell.

10. The display apparatus claimed as claim 9, wherein the nucleus of the quantum dot is formed by mixing one or more of materials selected from the group consisting of ZnS, ZnO, GaN, ZnSe, CdS, ZnTe, GaSe, CdSe, CdTe, GaAs, InP, GaSb, InAs, Te, PbS, InSb, PbTe and PbSe;
the shell of the quantum dot is formed from any one of SiO, TiO, ZnO, SiO2 and MgO;
the organic ligands include S, P, COOH and NH4 groups.

11. The display apparatus claimed as claim 4, wherein the quantum dot includes: a nucleus; a shell formed outside the nucleus, and organic ligands formed on the outside of the shell.

12. The display apparatus claimed as claim 11, wherein the nucleus of the quantum dot is formed by mixing one or more of materials selected from the group consisting of ZnS, ZnO, GaN, ZnSe, CdS, ZnTe, GaSe, CdSe, CdTe, GaAs, InP, GaSb, InAs, Te, PbS, InSb, PbTe and PbSe;
the shell of the quantum dot is formed from any one of SiO, TiO, ZnO, SiO2 and MgO;
the organic ligands include S, P, COOH and NH4 groups.
